(19) United States
(12) Patent Application Publication
(10) Pub. No.: US 2025/0261307 A1
(43) Pub. Date: Aug. 14, 2025

(54) METHOD FOR MANUFACTURING LIQUID CRYSTAL POLYMER FILM, LIQUID CRYSTAL POLYMER FILM, METHOD FOR MANUFACTURING HIGH FREQUENCY CIRCUIT BOARD MATERIAL, AND METHOD FOR MANUFACTURING HIGH FREQUENCY CIRCUIT BOARD

(71) Applicant: ZACROS Corporation, Tokyo (JP)

(72) Inventors: Akira MASAKI, Tokyo (JP); Masao MINAKUCHI, Tokyo (JP); Shinichirou SUZUKI, Tokyo (JP); Junya KASAHARA, Tokyo (JP)

(21) Appl. No.: 18/853,037

(22) PCT Filed: Jun. 8, 2023
(86) PCT No.: PCT/IB2023/055931

§ 371 Date: Apr. 9, 2025

(30) Foreign Application Priority Data
Jun. 9, 2022 (JP) 2022-093792
Jun. 8, 2023 (JP) 2023-094967

(51) Int. Cl. H05K 1/03; B32B 15/08; B32B 15/20; H05K 1/02

(52) U.S. Cl. CPC H05K 1/0326; B32B 15/08; B32B 15/20; H05K 1/0237; B32B 2305/55; B32B 2307/30; B32B 2457/08; H05K 2201/0129; H05K 2201/0141

(57) ABSTRACT

The present invention relates to a method for manufacturing a liquid crystal polymer film having excellent strength, a liquid crystal polymer film manufactured by the method, a method for manufacturing a high frequency circuit board material, and a method for manufacturing a high frequency circuit board. More specifically, the present invention provides a method for manufacturing a liquid crystal polymer film including a thermoplastic liquid crystal polymer film and a thermoplastic liquid crystal polymer layer, the method for manufacturing a liquid crystal polymer film including forming the thermoplastic liquid crystal polymer layer on a surface of the thermoplastic liquid crystal polymer film using a liquid thermoplastic liquid crystal polymer, a liquid crystal polymer film manufactured by the method, a method for manufacturing a high frequency circuit board material, and a method for manufacturing a high frequency circuit board.

### TECHNICAL FIELD

The present invention relates to a method for manufacturing a liquid crystal polymer film, a liquid crystal polymer film manufactured by the method, a method for manufacturing a high frequency circuit board material, and a method for manufacturing a high frequency circuit board.

### BACKGROUND ART

Patent Literature 1 describes that a liquid crystal polymer coating material is applied to a region where the thickness of a liquid crystal polymer resin layer is insufficient in the manufacturing of a resin multilayer board.

Patent Literature 2 describes that a paste containing the same thermoplastic resin is applied to a part of a resin sheet containing, as a main component, a liquid crystal polymer in which electronic components are integrated.

Patent Literature 3 describes that when a dispersion liquid of a powdery thermoplastic resin material is applied to a surface of a thermoplastic resin layer, a main material of the thermoplastic resin material is a liquid crystal polymer and is the same as the main material of the thermoplastic resin layer.

Patent Literature 4 describes that a paste containing a powder of a liquid crystal polymer is applied to a main surface of a resin layer mainly composed of the liquid crystal polymer on which a conductor pattern is disposed.

### CITATION LIST

### Patent Literature

Patent Literature 1: International Publication No. WO 2014/109139
Patent Literature 2: International Publication No. WO 2015/029783
Patent Literature 3: International Publication No. WO 2017/061423
Patent Literature 4: International Publication No. WO 2017/217126

### SUMMARY OF INVENTION

### Technical Problem

Since the liquid crystal polymer (LCP) has anisotropy, a film is easily torn, and manufacturing and handling are difficult.

The present invention has been made in view of the above circumstances, and an object of the present invention is to provide a method for manufacturing a liquid crystal polymer film having excellent strength, a liquid crystal polymer film manufactured by the method, a method for manufacturing a high frequency circuit board material, and a method for manufacturing a high frequency circuit board.

### Solution to Problem

In order to solve the above problems, the present invention provides a method for manufacturing a liquid crystal polymer film including a thermoplastic liquid crystal polymer film and a thermoplastic liquid crystal polymer layer, the method for manufacturing a liquid crystal polymer film including forming the thermoplastic liquid crystal polymer layer on a surface of the thermoplastic liquid crystal polymer film using a liquid thermoplastic liquid crystal polymer.

The forming the thermoplastic liquid crystal polymer layer is preferably applying a thermoplastic liquid crystal polymer solution.

The forming the thermoplastic liquid crystal polymer layer is preferably extruding a molten thermoplastic liquid crystal polymer.

The thermoplastic liquid crystal polymer solution is preferably applied by a method selected from the group consisting of die coating, gravure coating, screen printing, and inkjet printing.

The thermoplastic liquid crystal polymer film is preferably manufactured by a method selected from the group consisting of melt extrusion, stretching, an inflation method, and a solution casting method.

The thermoplastic liquid crystal polymer film is preferably a film of liquid crystal polyester or liquid crystal polyester amide, and the thermoplastic liquid crystal polymer layer is preferably a layer of liquid crystal polyester or liquid crystal polyester amide.

The present invention also provides a liquid crystal polymer film manufactured by the method for manufacturing a liquid crystal polymer film.

An elastic modulus in a TD direction of the liquid crystal polymer film obtained by forming the thermoplastic liquid crystal polymer layer preferably has a value larger than the elastic modulus in the TD direction of the thermoplastic liquid crystal polymer film before the thermoplastic liquid crystal polymer layer is formed.

An anisotropy of a linear expansion coefficient (CTE) of the liquid crystal polymer film obtained by forming the thermoplastic liquid crystal polymer layer preferably has a value smaller than the anisotropy of the linear expansion coefficient (CTE) of the thermoplastic liquid crystal polymer film before the thermoplastic liquid crystal polymer layer is formed.

The liquid crystal polymer film is preferably used for manufacturing a high frequency circuit board material.

The present invention also provides a method for manufacturing a high frequency circuit board material, the method including: manufacturing a liquid crystal polymer film by the method for manufacturing a liquid crystal polymer film; and laminating a copper foil on a surface of the thermoplastic liquid crystal polymer film on a side opposite to the thermoplastic liquid crystal polymer layer.

Furthermore, the present invention provides a method for manufacturing a high frequency circuit board, the method including: manufacturing a liquid crystal polymer film by the method for manufacturing a liquid crystal polymer film; laminating a copper foil on a surface of the thermoplastic liquid crystal polymer film on a side opposite to the thermoplastic liquid crystal polymer layer; and forming a circuit from the copper foil.

### Advantageous Effects of Invention

According to the present invention, a method for manufacturing a liquid crystal polymer film having excellent strength can be provided. In addition, the obtained liquid crystal polymer film can be used to manufacture a high frequency circuit board material and a high frequency circuit board having excellent dielectric properties.

### BRIEF DESCRIPTION OF DRAWINGS

FIG. 1 is a cross-sectional view illustrating an example of a liquid crystal polymer film of the present invention.

### DESCRIPTION OF EMBODIMENTS

Hereinafter, the present invention will be described based on preferred embodiments.

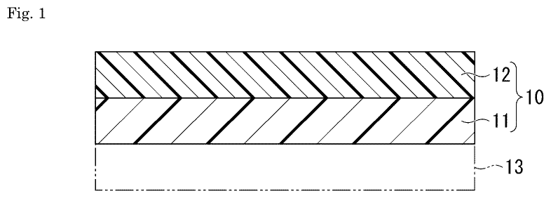

FIG. 1 schematically illustrates an example of a liquid crystal polymer film 10.

The liquid crystal polymer film 10 includes, on a surface of a thermoplastic liquid crystal polymer film 11, a thermoplastic liquid crystal polymer layer 12 formed using a liquid thermoplastic liquid crystal polymer.

A method for manufacturing the liquid crystal polymer film 10 includes forming the thermoplastic liquid crystal polymer layer 12 on the surface of the thermoplastic liquid crystal polymer film 11 using a liquid thermoplastic liquid crystal polymer.

The thermoplastic liquid crystal polymer film 11 can be manufactured by a method selected from the group consisting of melt extrusion, stretching, an inflation method, and a solution casting method. The thermoplastic liquid crystal polymer film 11 preferably has a strength capable of maintaining a shape even in a single layer. If necessary, processing such as coating may be performed while the thermoplastic liquid crystal polymer film 11 is supported.

The thermoplastic liquid crystal polymer film 11 is not particularly limited as long as it is a film of a thermoplastic resin having liquid crystallinity, and is preferably a film of liquid crystal polyester or liquid crystal polyester amide.

The thermoplastic liquid crystal polymer layer 12 may be a layer formed using a liquid thermoplastic liquid crystal polymer. Although not particularly limited, examples thereof include a coating layer obtained by applying a thermoplastic liquid crystal polymer solution, and an extrusion layer obtained by extruding a molten thermoplastic liquid crystal polymer.

The coating layer of the thermoplastic liquid crystal polymer is not particularly limited, and can be formed by applying a thermoplastic liquid crystal polymer solution by a method selected from the group consisting of die coating, gravure coating, screen printing, and inkjet printing.

The extrusion layer of the thermoplastic liquid crystal polymer is not particularly limited, and can be formed using a T-die or the like. Melting of the thermoplastic liquid crystal polymer is not particularly limited, and an extruder including a screw and the like can be used.

The thermoplastic liquid crystal polymer layer 12 is not particularly limited as long as it is a layer of a thermoplastic resin having liquid crystallinity, is preferably a layer of liquid crystal polyester or liquid crystal polyester amide, and may be a coating layer or an extrusion layer of liquid crystal polyester or liquid crystal polyester amide.

The thermoplastic liquid crystal polymer solution to be used for formation of the coating layer of the thermoplastic liquid crystal polymer is not particularly limited as long as it is a solution of a thermoplastic resin having liquid crystallinity, and is preferably a solution of liquid crystal polyester or liquid crystal polyester amide.

The same thermoplastic liquid crystal polymer may be used for the thermoplastic liquid crystal polymer film 11 and the thermoplastic liquid crystal polymer layer 12, or different thermoplastic liquid crystal polymers may be used. Both may be liquid crystal polyesters or liquid crystal polyester amides, or a combination of liquid crystal polyester and liquid crystal polyester amide may be used.

In the liquid crystal polyester, the main chain of the liquid crystal polymer may have an ester bond repeatedly. In the liquid crystal polyester amide, the main chain of the liquid crystal polymer may have an ester bond and an amide bond repeatedly.

The thermoplastic liquid crystal polymer layer 12 can be formed on at least one surface of the thermoplastic liquid crystal polymer film 11. In order to dispose the thermoplastic liquid crystal polymer film 11 on one surface of the liquid crystal polymer film 10, the thermoplastic liquid crystal polymer layer 12 is preferably formed only on one surface of the thermoplastic liquid crystal polymer film 11. The thermoplastic liquid crystal polymer layer 12 may be formed on both surfaces of the liquid crystal polymer film 10.

When the thermoplastic liquid crystal polymer layer 12 is formed, the thermoplastic liquid crystal polymer film 11 may be conveyed in a roll-to-roll manner. The thermoplastic liquid crystal polymer layer 12 may be formed over the entire surface of the thermoplastic liquid crystal polymer film 11, or may be formed in a partial region such as a region excluding both ends in a width direction of the thermoplastic liquid crystal polymer film 11.

The liquid thermoplastic liquid crystal polymer used for coating, melt extrusion, and the like preferably does not contain particles, and particularly preferably does not include a particle diameter larger than a film thickness of the thermoplastic liquid crystal polymer layer 12.

The thermoplastic liquid crystal polymer solution used for coating is preferably a solution in which a solvent-soluble thermoplastic liquid crystal polymer is dissolved in a solvent.

The solvent used in the thermoplastic liquid crystal polymer solution is not particularly limited as long as it is a solvent capable of dissolving the thermoplastic liquid crystal polymer, examples thereof include polar solvents such as an ether-based solvent, a ketone-based solvent, an ester-based solvent, a carbonate-based solvent, an amide-based solvent, a nitrile-based solvent, and a sulfur-containing compound-based solvent, and the solvent may be an aprotic polar solvent.

Examples of the ether-based solvent include diethyl ether (DEE), tetrahydrofuran (THF), and dioxane.

Examples of the ketone-based solvent include acetone and methyl ethyl ketone (MEK).

Examples of the ester-based solvent include acyclic ester-based solvents such as ethyl acetate (EA) and cyclic ester-based solvents (lactone-based solvents) such as y-butyrolactone.

Examples of the carbonate-based solvent include ethylene carbonate (EC) and propylene carbonate (PC).

Examples of the amide-based solvent include dimethylformamide (DMF), dimethylacetamide (DMA), and N-methylpyrrolidone (NMP).

Examples of the nitrile-based solvent include acetonitrile (AN), propionitrile, and succinonitrile.

Examples of the sulfur-containing compound-based solvent include dimethyl sulfoxide (DMSO) and sulfolane.

When the thermoplastic liquid crystal polymer solution is applied to form the thermoplastic liquid crystal polymer layer 12, the condition for drying the solvent after the application is not particularly limited as long as a state in which the solvent is sufficiently dried can be realized; however, as the temperature for drying the solvent, in order to enhance interlayer adhesion between the thermoplastic liquid crystal polymer film 11 and the thermoplastic liquid crystal polymer layer 12, heating is preferably performed at a temperature at which a polymerization reaction by transesterification occurs between liquid crystal polymer molecules in the thermoplastic liquid crystal polymer layer 12, and further between the liquid crystal polymer of the thermoplastic liquid crystal polymer film 11 and the liquid crystal polymer of the thermoplastic liquid crystal polymer layer 12, and the temperature for drying the solvent is, for example, preferably 180° C. or higher, more preferably 200° C. or higher, and still more preferably 250° C. or higher. From the viewpoint of suppressing oxidation degradation of the liquid crystal polymer, the temperature for drying the solvent is preferably 350° C. or lower, and more preferably 300° C. or lower. The time for drying the solvent is not particularly limited, and is preferably 30 minutes or more, and more preferably 1 hour or more. From the viewpoint of suppressing oxidation degradation of the liquid crystal polymer, the time for drying the solvent is preferably 5 hours or less, and more preferably 3 hours or less.

The liquid crystal polymer film 10 including the thermoplastic liquid crystal polymer layer 12 formed using a liquid thermoplastic liquid crystal polymer is superior in strength to the thermoplastic liquid crystal polymer film 11 before the thermoplastic liquid crystal polymer layer 12 is formed. For example, an elastic modulus of the liquid crystal polymer film 10 in a TD direction is preferably larger than the elastic modulus of the thermoplastic liquid crystal polymer film 11 in the TD direction.

The liquid crystal polymer film 10 including the thermoplastic liquid crystal polymer layer 12 formed using a liquid thermoplastic liquid crystal polymer preferably has lower anisotropy than that of the thermoplastic liquid crystal polymer film 11 before the thermoplastic liquid crystal polymer layer 12 is formed. For example, the anisotropy of a linear expansion coefficient (CTE) of the liquid crystal polymer film 10 preferably has a value smaller than the anisotropy of the linear expansion coefficient (CTE) of the thermoplastic liquid crystal polymer film 11.

The anisotropy of physical properties such as the linear expansion coefficient (CTE) can be expressed by a difference in physical properties in two directions orthogonal to each other on a film surface, for example, an absolute value of a difference between a value in an MD direction and a value in the TD direction. When values of the physical properties in the two directions are equal to each other, the anisotropy is zero. When the values of the physical properties in the two directions are different, the anisotropy is a positive value.

The TD direction and the MD direction when the thermoplastic liquid crystal polymer film 11 is formed by melt extrusion or the like may be the same as or different from the TD direction and the MD direction when the thermoplastic liquid crystal polymer layer 12 is formed from a liquid thermoplastic liquid crystal polymer.

When the thermoplastic liquid crystal polymer layer 12 is formed by coating, a method for treating the thermoplastic liquid crystal polymer film 11 is not particularly limited, and can be appropriately adopted. For example, the thermoplastic liquid crystal polymer solution may be applied to one surface of the thermoplastic liquid crystal polymer film 11 twice or more to laminate two or more thermoplastic liquid crystal polymer layers 12. The thermoplastic liquid crystal polymer solution may be applied simultaneously or sequentially onto both surfaces of the thermoplastic liquid crystal polymer film 11 to form the thermoplastic liquid crystal polymer layer 12.

When the thermoplastic liquid crystal polymer layer 12 is formed by melt extrusion, the method for treating the thermoplastic liquid crystal polymer film 11 is not particularly limited, and can be appropriately adopted. For example, the molten thermoplastic liquid crystal polymer may be extruded on one surface of the thermoplastic liquid crystal polymer film 11 twice or more to laminate two or more thermoplastic liquid crystal polymer layers 12. The molten thermoplastic liquid crystal polymer may be also extruded simultaneously or sequentially onto the both surfaces of the thermoplastic liquid crystal polymer film 11 to form the thermoplastic liquid crystal polymer layer 12.

When the thermoplastic liquid crystal polymer layers 12 are formed on the both surfaces of the thermoplastic liquid crystal polymer film 11, the respective methods for forming the thermoplastic liquid crystal polymer layers 12 may be the same or different. The thermoplastic liquid crystal polymer layer 12 may be formed on one surface of the same thermoplastic liquid crystal polymer film 11 by coating, and the thermoplastic liquid crystal polymer layer 12 may be formed on the other surface by melt extrusion.

The application of the liquid crystal polymer film 10 is not particularly limited, and the liquid crystal polymer film 10 can be used for, for example, a board of a circuit or the like corresponding to a high frequency, an insulating material, and the like. A laminated structure of the high frequency circuit board material is not particularly limited, and a conductor layer such as a copper foil may be provided on at least one surface of an insulating material such as a resin film.

The liquid crystal polymer film 10 includes the thermoplastic liquid crystal polymer layer 12 only on one surface of the thermoplastic liquid crystal polymer film 11, and a conductor layer such as a copper foil 13 may be laminated on the thermoplastic liquid crystal polymer film 11. In this case, a circuit or the like can be formed using a conductor layer such as the copper foil 13.

A method for forming a high frequency circuit from the conductor layer such as the copper foil 13 is not particularly limited, and examples thereof include etching and photolithography. A circuit pattern of the conductor layer is not particularly limited, and examples thereof include a wiring pattern and an antenna pattern. A hole may be formed in the liquid crystal polymer film 10 by a laser or the like, and a conductor portion penetrating the board may be formed in the hole using a conductive paste, plating, and the like.

The thermoplastic liquid crystal polymer film 11 is preferably more excellent in dielectric properties than the thermoplastic liquid crystal polymer layer 12, and for example, the values of dielectric constant and dielectric loss tangent are preferably lower than those of the thermoplastic liquid crystal polymer layer 12. By disposing the conductor layer such as the copper foil 13 on the thermoplastic liquid crystal polymer film 11 side, a circuit and the like having more excellent high frequency characteristics can be formed. The copper foil 13 may be laminated on a surface of the thermoplastic liquid crystal polymer film 11 on a side opposite to a surface on which the thermoplastic liquid crystal polymer layer 12 is formed.

The film thicknesses of the thermoplastic liquid crystal polymer film 11 and the thermoplastic liquid crystal polymer layer 12 are not particularly limited, and it is preferable that the film thickness of one having excellent dielectric properties is thicker. When the dielectric properties of the thermoplastic liquid crystal polymer film 11 are more excellent, the film thickness of the thermoplastic liquid crystal polymer layer 12 is more preferably a minimum film thickness capable of relaxing the anisotropy of the thermoplastic liquid crystal polymer film 11.

Specifically, when the film thickness of the thermoplastic liquid crystal polymer film 11 is 10 μm or more and less than 30 μm, the film thickness of the thermoplastic liquid crystal polymer layer 12 is preferably 0.5 μm or more and 8 μm or less, when the film thickness of the thermoplastic liquid crystal polymer film 11 is 30 μm or more and less than 60 μm, the film thickness of the thermoplastic liquid crystal polymer layer 12 is preferably 0.5 μm or more and 20 μm or less, and more preferably 0.5 μm or more and 15 μm or less, when the film thickness of the thermoplastic liquid crystal polymer film 11 is 60 μm or more and less than 90 μm, the film thickness of the thermoplastic liquid crystal polymer layer 12 is preferably 0.5 μm or more and 30 μm or less, and more preferably 0.5 μm or more and 20 μm or less, and when the film thickness of the thermoplastic liquid crystal polymer film 11 is 90 μm or more, the film thickness of the thermoplastic liquid crystal polymer layer 12 is preferably 0.5 μm or more and 50 μm or less, and more preferably 0.5 μm or more and 30 μm or less.

The thermoplastic liquid crystal polymer film 11 preferably has dielectric properties available for high frequencies used for current or next generation high speed and high capacity communications. The high frequency is preferably a frequency higher than 2 GHz, and specific examples thereof include high frequency bands of 3.7 GHz band, 4.5 GHz band, 28 GHz band, 90 to 300 GHz band, and higher. These frequency bands may have a width of, for example, about ±0.5 GHz or about ±1 GHz.

As the dielectric properties of the thermoplastic liquid crystal polymer film 11 at a high frequency, for example, the dielectric loss tangent at a measurement frequency of 10 GHz is preferably 0.002 or less. Among resins having excellent dielectric properties, the liquid crystal polymer is preferable as a high frequency circuit board material because it has low water absorbency as compared with polyimide and the like, and has excellent adhesion to a copper foil as compared with a fluororesin.

As described above, the liquid crystal polymer film 10 can be a resin film having both dielectric properties and tear propagation resistance by forming the thermoplastic liquid crystal polymer layer 12 using a liquid thermoplastic liquid crystal polymer on at least one surface of the thermoplastic liquid crystal polymer film 11.

Although the present invention has been described based on preferred embodiments, the present invention is not limited to the above-described embodiments, and various modifications can be made without departing from the gist of the present invention. Examples of the modifications include addition, replacement, omission, and other changes of components in embodiments.

### EXAMPLES

Hereinafter, the present invention will be specifically described with reference to Examples.

### (Liquid Crystal Polymer Film of Comparative Example)

The liquid crystal polymer film of Comparative Example is a film of a thermoplastic liquid crystal polyester manufactured by a melt extrusion method using a T-die. This thermoplastic liquid crystal polymer film (in which the thermoplastic liquid crystal polymer layer is not formed) is poor in tear propagation resistance to such an extent that at least the film is easily torn by hand in the TD direction. Thus, the liquid crystal polymer film of Comparative Example had such low strength that at least the elastic modulus in the TD direction could not be measured, and was insufficient for use as a board material.

### (Liquid Crystal Polymer Film of Example 1)

A polymer solution (solvent: N-methylpyrrolidone) of a solvent-soluble thermoplastic liquid crystal polyester was applied to one surface of a film of a thermoplastic liquid crystal polyester manufactured by a melt extrusion method, dried at 100° C. for 10 minutes, and then calcined at 230° C. for 60 minutes to manufacture a liquid crystal polymer film. The film thickness of the thermoplastic liquid crystal polymer layer formed by applying the polymer solution was about 10 μm, and the film thickness of the liquid crystal polymer film was 56 to 58 μm. The adhesion between the film of the thermoplastic liquid crystal polyester and the thermoplastic liquid crystal polymer layer was high, and the film could not be peeled off. The reason why such high adhesion has been achieved is considered to be that a transesterification reaction has occurred between the molecules in the thermoplastic liquid crystal polymer film and the molecules in the thermoplastic liquid crystal polymer layer during calcination, resulting in chemical bonding.

### (Measurement of Linear Expansion Coefficient)

A sample having a width of 4 mm and a length of 15 mm was cut out from the obtained liquid crystal polymer film to obtain a measurement sample, and the measurement was performed using a thermomechanical analyzer (manufactured by Hitachi High-Tech Science Corporation, product name “TMA 7100”). A tensile load applied to the measurement sample was set according to the film thickness of the sample (the load was set to 100 mN when the film thickness was 40 to 60 μm, and the load was set to 150 mN when the film thickness was 75 to 95 μm). The linear expansion coefficient was measured from a dimensional change according to a temperature change of the measurement sample. The measurement sample was heated from 30° C. to 250° C. at a temperature rising rate of 15° C./min, held at 250° C. for 10 minutes, then cooled to 30° C. at a temperature falling rate of 15° C./min, held at 30° C. for 5 minutes, and then heated again to 300° C. at a temperature rising rate of 10° C./min.

The linear expansion coefficient (CTE) of the liquid crystal polymer film of Comparative Example was −14 ppm/K in the MD direction, and 101 ppm/K in the TD direction, and the anisotropy of CTE was 115 ppm/K.

The linear expansion coefficient (CTE) of the liquid crystal polymer film of Example 1 was −9 ppm/K in the MD direction, and 72 ppm/K in the TD direction, and the anisotropy of CTE was 81 ppm/K.

As described above, in the liquid crystal polymer film obtained by applying the thermoplastic liquid crystal polymer solution, the value of anisotropy of CTE was small, and the anisotropy could be relaxed.

### (Measurement of Elastic Modulus)

A sample having a width of 4 mm and a length of 20 mm was cut out from the obtained liquid crystal polymer film to obtain a measurement sample, and the measurement was performed using a dynamic viscoelasticity measuring device (manufactured by TA Instruments Japan Inc., product name “ARES-G2”). The measurement temperature was set to 10 to 300° C. (temperature rising rate: 5° C./min), a strain of 0.3% was applied at a frequency of 1 Hz, and the elastic modulus was measured from a waveform of shear stress as a response and a phase difference thereof.

The elastic modulus of the liquid crystal polymer film obtained by applying the thermoplastic liquid crystal polymer solution was 17 GPa in the MD direction and 1.8 GPa in the TD direction. As a result, it was confirmed that the liquid crystal polymer film of Example had a larger elastic modulus than the thermoplastic liquid crystal polymer film before applying the thermoplastic liquid crystal polymer solution at least in the TD direction.

### (Liquid Crystal Polymer Film of Example 2)

A liquid crystal polymer film was manufactured in the same manner as in Example 1 except that a solvent-soluble thermoplastic liquid crystal polymer solution was applied, and dried at 100° C. for 10 minutes, and the calcination conditions were then set at 270° C. for 150 minutes, which facilitate the transesterification reaction between the molecules in the thermoplastic liquid crystal polymer film and the molecules in the thermoplastic liquid crystal polymer layer. The linear expansion coefficient (CTE) of the obtained liquid crystal polymer film was −1 ppm/K in the MD direction, and 17 ppm/K in the TD direction, and the anisotropy of CTE was 18 ppm/K. The obtained liquid crystal polymer film had an elastic modulus of 13 GPa in the MD direction and 8.4 GPa in the TD direction.

### (Liquid Crystal Polymer Film of Example 3)

A liquid crystal polymer film was manufactured in the same manner as in Example 2 except that a film was formed so that the film thickness of the thermoplastic liquid crystal polymer layer was about 15 μm and the film thickness of the liquid crystal polymer film was 70 to 72 μm. The linear expansion coefficient (CTE) of the obtained liquid crystal polymer film was −6 ppm/K in the MD direction, and 17 ppm/K in the TD direction, and the anisotropy of CTE was 23 ppm/K. The elastic modulus of the obtained liquid crystal polymer film was 18 GPa in the MD direction and 11 GPa in the TD direction.

### REFERENCE SIGNS LIST

10 Liquid crystal polymer film
11 Thermoplastic liquid crystal polymer film
12 Thermoplastic liquid crystal polymer layer
13 Copper foil

1: A method for manufacturing a liquid crystal polymer film including a thermoplastic liquid crystal polymer film and a thermoplastic liquid crystal polymer layer, the method for manufacturing a liquid crystal polymer film comprising forming the thermoplastic liquid crystal polymer layer on a surface of the thermoplastic liquid crystal polymer film using a liquid thermoplastic liquid crystal polymer.

2: The manufacturing method according to claim 1, wherein the forming the thermoplastic liquid crystal polymer layer is applying a thermoplastic liquid crystal polymer solution.

3: The manufacturing method according to claim 1, wherein the forming the thermoplastic liquid crystal polymer layer is extruding a molten thermoplastic liquid crystal polymer.

4: The manufacturing method according to claim 2, wherein the thermoplastic liquid crystal polymer solution is applied by a method selected from the group consisting of die coating, gravure coating, screen printing, and inkjet printing.

5: The manufacturing method according to claim 1, wherein the thermoplastic liquid crystal polymer film is manufactured by a method selected from the group consisting of melt extrusion, stretching, an inflation method, and a solution casting method.

6: The manufacturing method according to claim 1, wherein the thermoplastic liquid crystal polymer film is a film of liquid crystal polyester or liquid crystal polyester amide, and the thermoplastic liquid crystal polymer layer is a layer of liquid crystal polyester or liquid crystal polyester amide.

7: A liquid crystal polymer film manufactured by the manufacturing method according to claim 1.

8: The liquid crystal polymer film according to claim 7, wherein an elastic modulus in a TD direction of the liquid crystal polymer film obtained by forming the thermoplastic liquid crystal polymer layer has a value larger than the elastic modulus in the TD direction of the thermoplastic liquid crystal polymer film before the thermoplastic liquid crystal polymer layer is formed.

9: The liquid crystal polymer film according to claim 7, wherein an anisotropy of a linear expansion coefficient (CTE) of the liquid crystal polymer film obtained by forming the thermoplastic liquid crystal polymer layer has a value smaller than the anisotropy of the linear expansion coefficient (CTE) of the thermoplastic liquid crystal polymer film before the thermoplastic liquid crystal polymer layer is formed.

10: The liquid crystal polymer film according to claim 7, which is used for manufacturing a high frequency circuit board material.

11: A method for manufacturing a high frequency circuit board material, the method comprising:
manufacturing a liquid crystal polymer film by the manufacturing method according to claim 1; and
laminating a copper foil on a surface of the thermoplastic liquid crystal polymer film on a side opposite to the thermoplastic liquid crystal polymer layer.

12: A method for manufacturing a high frequency circuit board, the method comprising:
manufacturing a liquid crystal polymer film by the manufacturing method according to claim 1;
laminating a copper foil on a surface of the thermoplastic liquid crystal polymer film on a side opposite to the thermoplastic liquid crystal polymer layer; and
forming a circuit from the copper foil.
